(19) United States
(12) Patent Application Publication
(10) Pub. No.: US 2020/0251565 A1
(43) Pub. Date: Aug. 6, 2020

(54) GATE STRUCTURE OF SPLIT-GATE METAL OXIDE SEMICONDUCTOR FIELD EFFECT TRANSISTOR AND MANUFACTURING METHOD THEREOF

(71) Applicant: Silicongear Corporation, Hsinchu County (TW)

(72) Inventors: Jiong-Guang Su, Hsinchu County (TW); Shao-Hua Chen, Taipei City (TW); Hung-Wen Chou, Hsinchu County (TW)

(73) Assignee: Silicongear Corporation, Hsinchu County (TW)

(21) Appl. No.: 16/532,504

(22) Filed: Aug. 6, 2019

(30) Foreign Application Priority Data
Feb. 1, 2019 (TW) 108104022

(51) Int. Cl. H01L 29/423; H01L 29/78; H01L 29/66; H01L 21/283; H01L 21/308

(52) U.S. Cl. CPC H01L 29/4236; H01L 29/7851; H01L 21/3086; H01L 21/283; H01L 29/66795

(57) ABSTRACT

A gate structure of split-gate MOSFET includes a substrate, an epitaxial layer, a first gate, a second gate, a bottom dielectric layer between the first gate and the epitaxial layer, a gate dielectric layer between the second gate and the epitaxial layer, and an inter-gate dielectric layer between the first and second gates. The epitaxial layer is on the substrate having first and second trenches with different extending directions, wherein the first trench and the second trench have an overlapping region. The width of the first trench is greater than that of the second trench. The depth of the first trench is greater than that of the second trench. The first gate is in the first trench. The second gate is in the first trench on the first gate and in the second trenches.

### CROSS-REFERENCE TO RELATED APPLICATION

This application claims the priority benefit of Taiwan application serial no. 108104022, filed on Feb. 1, 2019. The entirety of the above-mentioned patent application is hereby incorporated by reference herein and made a part of specification.

### BACKGROUND

### Technical Field

The disclosure relates to a trench type metal oxide semiconductor field effect transistor (MOSFET), and more particularly to a gate structure of a split-gate MOSFET and a manufacturing method thereof.

### Description of Related Art

A split-gate MOSFET may also be referred to as a shielded-gate MOSFET, which is structured by dividing the gate structure in the trench type MOSFET into a control gate and a shielded gate. Moreover, the split-gate MOSFET has the advantages of low on-resistance and low-miller capacitance compared to a single-gate MOSFET if both are with identical breakdown voltage.

For the split-gate MOSFET, it is required to let the bottom layer in the trench to be a thick dielectric layer, and therefore the size of the trench cannot be reduced. As a result, when manufacturing the low breakdown voltage element, since the critical dimension (CD) of the trench cannot be effectively reduced to increase the channel density of the element, the channel resistance in the on-resistance cannot be effectively decreased. For the low breakdown voltage element, since the on-resistance is mostly composed of the channel resistance, on basis of the same low breakdown voltage, the split-gate MOSFET cannot effectively reduce the on-resistance as compared with the single-gate MOSFET.

### SUMMARY

The disclosure provides a gate structure of a split-gate metal oxide semiconductor field effect transistor (MOSFET), which can effectively increase the channel density of element, thereby reducing the overall channel resistance while serving the function of the split-gate power MOSFET.

The disclosure further provides a manufacturing method of a gate structure of a split-gate MOSFET, which can manufacture a gate structure of a control gate having a large area to reduce channel resistance while serving the function of the split-gate power MOSFET.

The gate structure of the split-gate MOSFET of the disclosure includes a substrate, an epitaxial layer, a first gate, a second gate, a bottom dielectric layer, a gate dielectric layer and an inter-gate dielectric layer. The epitaxial layer is formed on the substrate, and has a first trench and a second trench with different extending directions, wherein the first trench and the second trench have an overlapping region. The width of the first trench is greater than the width of the second trench, and the depth of the first trench is greater than the depth of the second trench. The first gate is located in the first trench. The second gate is located in the first trench on the first gate and located in the second trench. The bottom dielectric layer is disposed between the first gate and the epitaxial layer. The gate dielectric layer is disposed between the second gate and the epitaxial layer. The inter-gate dielectric layer is disposed between the first gate and the second gate.

In an embodiment of the disclosure, a ratio of the width of the second trench to the width of the first trench is to effectively exhibit micro-loading effect of etch rate.

In an embodiment of the disclosure, a ratio of the depth of the second trench to the depth of the first trench is 0.8 or less.

In an embodiment of the disclosure, the first gate may further include an extending portion extending from the first trench into the second trench.

In an embodiment of the disclosure, the inter-gate dielectric layer may further be disposed between an extending portion and the second gate.

In an embodiment of the disclosure, the first trench and the second trench are arranged in a cross shape or a grid shape.

In an embodiment of the disclosure, the first trench and the second trench are arranged in T-shape.

In an embodiment of the disclosure, the material of the first gate and the second gate includes polysilicon.

In an embodiment of the disclosure, the epitaxial layer includes an N-type doped epitaxial layer or a P-type doped epitaxial layer.

A manufacturing method of a gate structure of a split-gate MOSFET of the disclosure includes forming an epitaxial layer on a substrate, and forming a patterned photomask on the epitaxial layer. The patterned photomask has a first opening and a second opening extending in different directions, wherein the first opening and the second opening have an overlapping region, and the width of the first opening is greater than the width of the second opening. Then, the patterned photomask is used as a mask for etching the epitaxial layer to form the first trench and the second trench in the epitaxial layer, wherein the first trench and the second trench have an overlapping region. The width of the first trench is greater than the width of the second trench, and the depth of the first trench is greater than the depth of the second trench. A bottom dielectric layer is formed on the surfaces of the first trench and the second trench. After a conductive material is formed in the first trench and the second trench, the conductive material is etched back to form the first gate and expose a portion of the bottom dielectric layer. Then, the exposed bottom dielectric layer is removed, and a thermal oxidation method is performed to form a gate dielectric layer on the sidewalls in the first trench and the second trench and form an inter-gate dielectric layer on the first gate simultaneously. Then, the second gate is formed in the first trench and the second trench.

In another embodiment of the disclosure, the method of forming the bottom dielectric layer includes a deposition method or a thermal oxidation method.

In another embodiment of the disclosure, a ratio of the width of the second opening to the width of the first opening is to effectively exhibit micro-loading effect of etch rate.

In another embodiment of the disclosure, a ratio of the depth of the second trench to the depth of the first trench is 0.8 or less.

In another embodiment of the disclosure, the method of forming the inter-gate dielectric layer includes completely and thermally oxidizing the conductive material within the second trench.

In another embodiment of the disclosure, the method of forming the inter-gate dielectric layer includes partially and thermally oxidizing the conductive material in the second trench to form an extending portion of the first gate extending from the first trench into the second trench.

In another embodiment of the disclosure, the material of the first gate and the second gate includes polysilicon.

In another embodiment of the disclosure, the epitaxial layer includes an N-type doped epitaxial layer or a P-type doped epitaxial layer.

Based on the above, with the gate structure of the split-gate MOSFET in the disclosure, it is possible to increase the area of the control gate and the device channel density through the first trench and the second trench having different extending directions. As a result, the channel resistance in the on-resistance can be effectively reduced. Moreover, according to the manufacturing method of the disclosure, by forming the photomask having openings with different widths, it is possible to simultaneously etch and form the trenches having different depths and widths. Therefore, the process of the disclosure can be integrated into the existing process without an additional photolithography process to manufacture a split-gate MOSFET of the control gate having a large area.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1A is a schematic cross-sectional view of a gate structure of a split-gate metal oxide semiconductor field effect transistor (MOSFET) according to an embodiment of the disclosure.

FIG. 1B is a schematic cross-sectional view showing another modification of FIG. 1A.

FIG. 2A is a top view of a gate structure of a split-gate MOSFET according to another embodiment of the disclosure.

FIG. 2B is a top view showing another modification of FIG. 2A.

FIG. 3A to FIG. 3I are schematic cross-sectional views showing a manufacturing process taken along line A-A′ of FIG. 2A.

### DESCRIPTION OF THE EMBODIMENTS

The exemplary embodiments of the disclosure will be more comprehensively described below with reference to the drawings, but the disclosure may be further implemented in many different forms and should not be construed as limited to the embodiments described herein. In the drawings, for clarity of illustration, the size and thickness of various regions, portions and layers may not be illustrated based on actual proportions. In addition, similar or identical reference numerals used in the drawings tend to represent similar or identical devices. Similar reference numerals in the drawings denote similar devices and related descriptions will be omitted.

In addition, terms such as “comprise,” “include,” “have” and the like used herein are all open terms, which mean including but not limited to. Moreover, directional terms mentioned herein, such as “on,” “below,” “left” and “right,” are only directions relative to the drawings. Therefore, the directional terms are used to illustrate rather than to limit the disclosure.

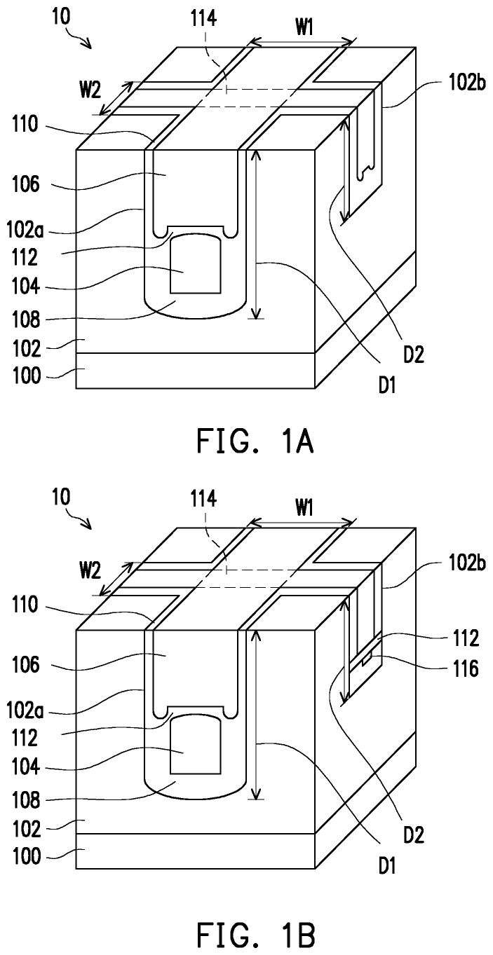

FIG. 1A is a schematic cross-sectional view of a gate structure of a split-gate metal oxide semiconductor field effect transistor (MOSFET) according to an embodiment of the disclosure.

Referring to FIG. 1A, a gate structure 10 of a split-gate MOSFET of the present embodiment at least includes a substrate 100, an epitaxial layer 102, a first gate 104, a second gate 106, a bottom dielectric layer 108, a gate dielectric layer 110, and an inter-gate dielectric layer 112. In the present embodiment, the disclosure provides no limitation to the substrate 100 and the substrate may be a silicon substrate.

In this embodiment, the epitaxial layer 102 is formed on the substrate 100, the substrate 100 may be an N-type substrate or a P-type substrate, and the epitaxial layer 102 may also be an N-type doped epitaxial layer or a P-type doped epitaxial layer. Preferably, the epitaxial layer 102 is, for example, an N-type doped epitaxial layer. The epitaxial layer 102 has a first trench 102a and a second trench 102b having different extending directions. The first trench 102a and the second trench 102b have an overlapping region 114. A width W1 of the first trench 102a is greater than a width W2 of the second trench 102b, and a depth D1 of the first trench 102a is greater than a depth D2 of the second trench 102b. In the present embodiment, a ratio of the width W2 of the second trench 102b to the width W1 of the first trench 102a is, for example, to effectively exhibit micro-loading effect of etch rate. When W2/W1 is less than 1, it is advantageous to use only one photolithography process, that is, to complete the first trench 102a and the second trench 102b having different depths. Referring to FIG. 1A, the first gate 104 is located in the first trench 102a. The second gate 106 is located in the first trench 102a on the first gate 104 and in the second trench 102b. The material of the first gate 104 and the second gate 106 is, for example, polysilicon or other suitable conductive materials, and the forming method thereof is, for example, chemical vapor deposition (CVD), physical vapor deposition (PVD) or other suitable process. In this embodiment, the first gate 104 may serve as a shielded gate, and the second gate 106 may serve as a control gate for controlling on/off of the split-gate MOSFET. Further, in the present embodiment, a ratio of the depth D2 of the second trench 102b to the depth D1 of the first trench 102a is, for example, 0.8 or less. When D2/D1 is 0.8 or less, it is helpful for the first gate 104 to be formed only in the first trench 102a.

Referring to FIG. 1A, the bottom dielectric layer 108 is located between the first gate 104 and the epitaxial layer 102. In the present embodiment, the method of forming the bottom dielectric layer 108 is, for example, a deposition method or a thermal oxidation method, but the disclosure is not limited thereto. For example, the bottom dielectric layer 108 manufactured using the thermal oxidation is, for example, subjected to a higher process temperature (e.g., 900° C. to 1200° C.) during the manufacturing process, so that the formed silicon oxide has higher compactness to serve as the surface protection in the pre-process (i.e., before the first gate 104 and the second gate 106 are formed).

In this embodiment, the gate dielectric layer 110 is located between the second gate 106 and the epitaxial layer 102. That is, the gate dielectric layer 110 is formed on the sidewalls of the first trench 102a and the second trench 102b. In an embodiment, the method of forming the gate dielectric layer 110 is, for example, a thermal oxidation method.

Referring to FIG. 1A, the inter-gate dielectric layer 112 is located between the first gate 104 and the second gate 106, wherein the material of the inter-gate dielectric layer 112 is, for example, silicon oxide, a composite layer of silicon oxide, or other material of silicon oxide. In addition, due to the manufacturing process, the inter-gate dielectric layer 112 may also be located between the bottom dielectric layer 108 in the second trench 102a and the second gate 106 (not shown). In an embodiment, the inter-gate dielectric layer 112 is, for example, a single-layer structure or a multilayer structure. In the present embodiment, the inter-gate dielectric layer 112 is exemplified as a single-layer structure. Moreover, in another embodiment, the inter-gate dielectric layer 112 may be formed simultaneously with the gate dielectric layer 110 through design of the process, but the disclosure is not limited thereto.

Since the width W1 of the first trench 102a of the embodiment is greater than the width W2 of the second trench 102b, and when the ratio (W2/W1) of the widths is controlled to effectively exhibit micro-loading effect of etch rate, it is possible to increase the area of the second gate 106 (control gate) while using only one photomask to complete trenches with different depths. Therefore, the channel density of element can be effectively increased and the channel resistance can be reduced without dramatically changing the existing process.

FIG. 1B is a schematic cross-sectional view showing another modification of FIG. 1A. The same or similar portions are denoted by the same reference numerals used in FIG. 1A, and related descriptions are omitted herein.

Please refer to FIG. 1B. The difference between the structures of FIG. 1B and FIG. 1A is that the first gate 104 may further include an extending portion 116 extending from the first trench 102a into the second trench 102b, and the extending portion 116 is located between the epitaxial layer 102 and the inter-gate dielectric layers 112. Specifically, the extending portion 116 is a part of the first gate 104, and therefore the material thereof is the same as that of the first gate 104, for example, polysilicon. In the embodiment, since the extending portion 116 has the same potential as the first gate 104, the performance of the first gate 104 can be improved in terms of lowering the gate-to-drain capacitance (C_{gd}) and increasing the breakdown voltage. Moreover, the structure of the first gate 104 may be changed as needed, and is not limited to the contents shown in FIG. 1A or FIG. 1B.

Further, in addition to the above-described embodiments of FIG. 1A and FIG. 1B, the gate structure 10 of the split-gate MOSFET of the disclosure may have other modifications.

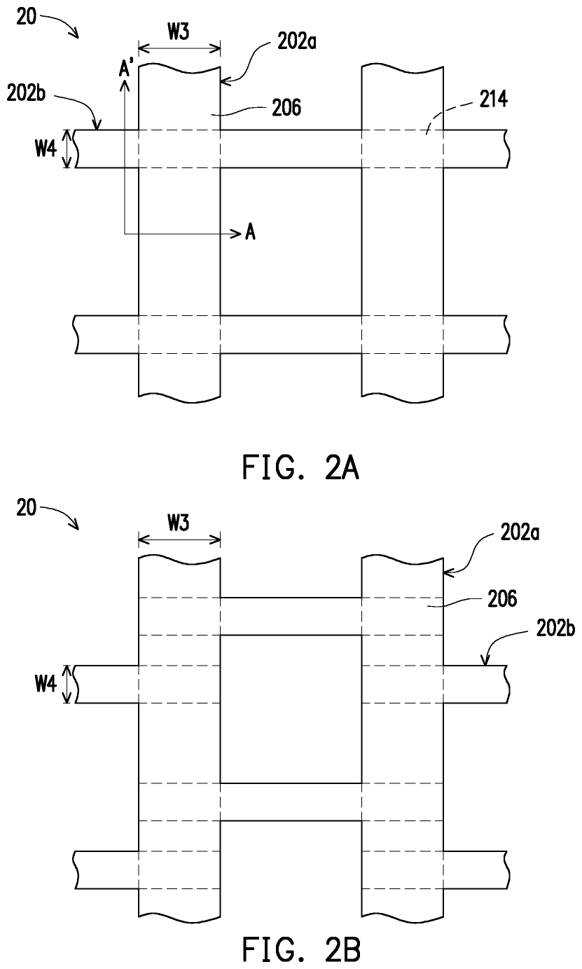

FIG. 2A is a top view of a gate structure of a split-gate MOSFET according to another embodiment of the disclosure. FIG. 2B is a top view showing another modification of FIG. 2A.

Hereinafter, FIG. 2A will be used to describe the top view of a gate structure 20 of a split-gate MOSFET according to an embodiment of the disclosure, wherein the same or similar elements are denoted by the same or similar reference numerals. The materials, processes, and effects have been described in detail in the above embodiments, and thus are not described again.

Referring to FIG. 2A, in the embodiment, the first trench 202a and the second trench 202b are arranged in a cross shape or a grid shape, wherein the second gate 206 is disposed in the first trench 202a and the second trench 202b, and the first trench 202a and the second trench 202b have an overlapping region 214. In another embodiment, the first trench 202a and the second trench 202b are arranged in T-shape (as shown in FIG. 2B), but the disclosure is not limited thereto, and the relative positions of the first trench 202a and the second trench 202b may be adjusted as needed.

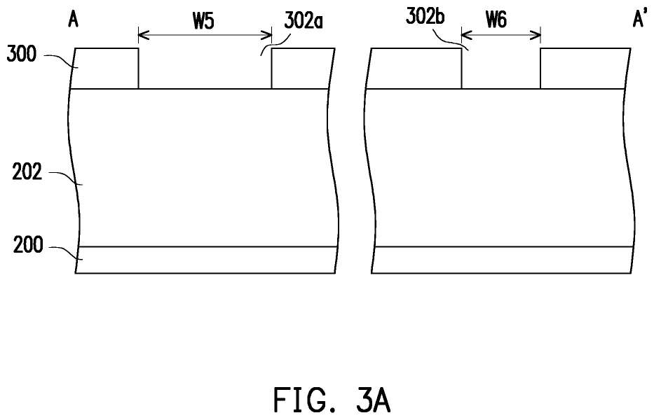

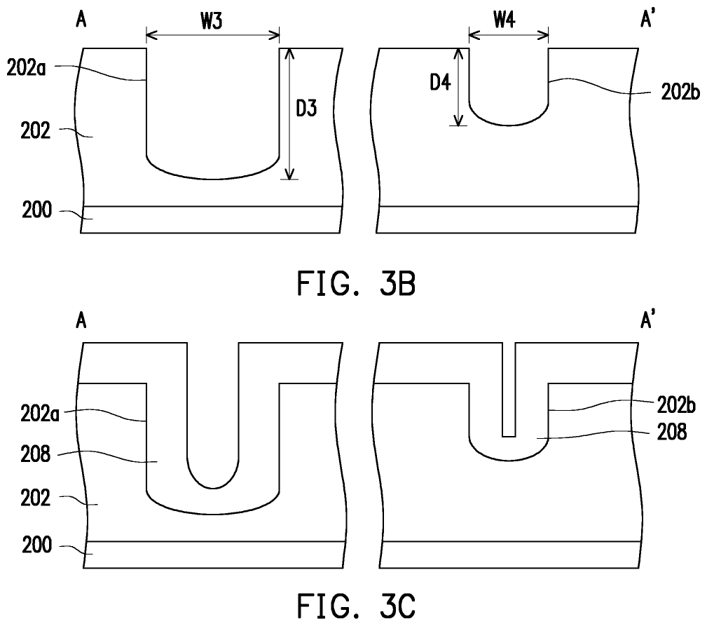

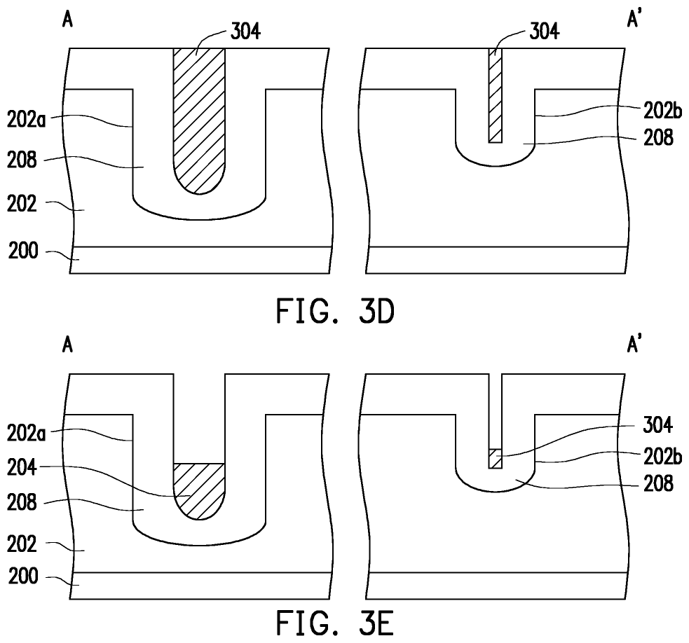

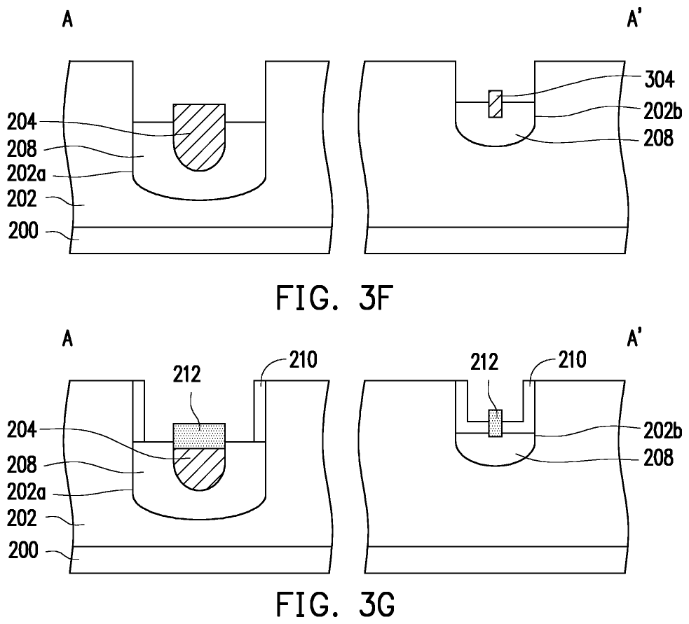

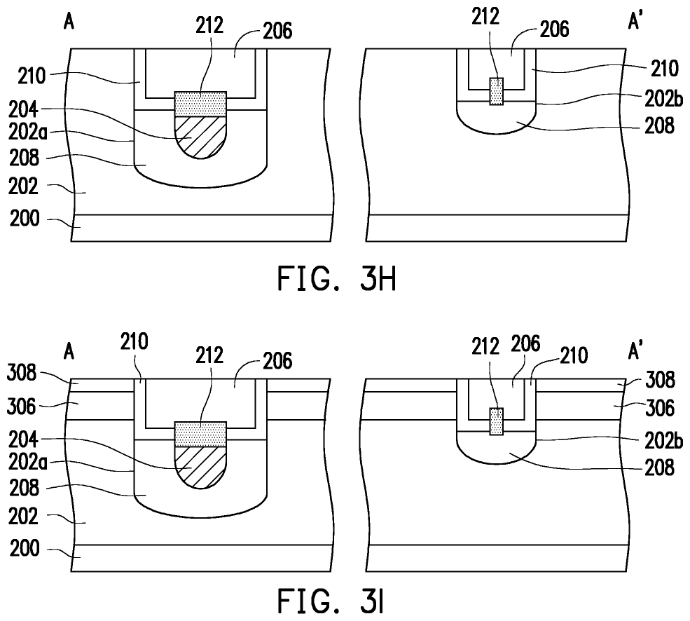

FIG. 3A to FIG. 3I are schematic cross-sectional views showing a manufacturing process taken along line A-A′ of FIG. 2A.

Referring to FIG. 3A first, an epitaxial layer 202 is formed on a substrate 200. In the present embodiment, the disclosure provides no limitation to the substrate 200. The epitaxial layer 202 is, for example, an N-type doped epitaxial layer. Thereafter, a patterned photomask 300 is formed on the epitaxial layer 202 to expose a portion of the epitaxial layer 202. That is, the patterned photomask 300 on the epitaxial layer 202 has a first opening 302a and a second opening 302b with different extending directions, wherein the first opening 302a and the second opening 302b have an overlapping region, and the width W5 of the first opening 302a is greater than the width W6 of the second opening 302b, wherein a ratio of the width W6 of the second opening 302b to the width W5 of the first opening 302a is, for example, to effectively exhibit micro-loading effect of etch rate. When W6/W5 is to effectively exhibit micro-loading effect of etch rate, it is advantageous to subsequently form trenches having different depths by using one photolithography process.

Next, referring to FIG. 3B, the epitaxial layer 202 is etched by using the patterned photomask 300 as a mask to form the first trench 202a and the second trench 202b, and then the patterned photomask 300 is removed. The first trench 202a and the second trench 202b have an overlapping region 214 (shown in FIG. 2A), and the width W3 of the first trench 202a is greater than the width W4 of the second trench 202b. In detail, since the widths of the first opening 302a and the second opening 302b of the patterned photomask 300 are different, the depths of the first trench 202a and the second trench 202b formed after the etching process are different; that is, the depth D3 of the wider first trench 202a may be greater than the depth D4 of the narrower second trench 202b.

In the present embodiment, a ratio of the width W4 of the second trench 202b to the width W3 of the first trench 202a is to effectively exhibit micro-loading effect of etch rate. In addition, in this embodiment, a ratio of the depth D4 of the second trench 202b to the depth D3 of the first trench 202a may be 0.8 or less.

Then, referring to FIG. 3C, a bottom dielectric layer 208 is formed on the surfaces of the first trench 202a and the second trench 202b. A method of forming the bottom dielectric layer 208 is, for example, a deposition method or a thermal oxidation method. For example, when the bottom dielectric layer 208 is formed by using the thermal oxidation method, a higher process temperature (for example, 900° C. to 1200° C.) may be adopted, and thus the material (for example, silicon dioxide) of the formed bottom dielectric layer 208 has high compactness.

Next, referring to FIG. 3D, a conductive material 304 is formed in the first trench 202a and the second trench 202b, wherein the conductive material 304 is, for example, a polysilicon. In this embodiment, the step of forming the conductive material 304 is as follows: first, the conductive material 304 is formed in the first trench 202a and the second trench 202b by using a chemical vapor deposition, a physical vapor deposition or other suitable film forming process. Thereafter, the conductive material 304 outside the first trench 202a and the second trench 202b is removed by using a chemical mechanical polishing (CMP) or an etching method. Referring to FIG. 3E, the conductive material 304 may be etched back to form the first gate 204 in the first trench 202a, and expose a portion of the bottom dielectric layer 208 in the first trench 202a and the second trench 202b. In addition, in other embodiments, a CMP process may be performed first in the etching-back process to remove the conductive material 304 outside the first trench 202a.

Next, referring to FIG. 3F, the exposed bottom dielectric layer 208 is removed. In the present embodiment, the method of removing the exposed bottom dielectric layer 206 is performed, for example, by performing a wet etching process to remove a portion of the bottom dielectric layer 208 in the first trench 202a and the second trench 202b. The process of removing the bottom dielectric layer 208 is performed continuously such that a portion of the first gate 204 and a portion of the conductive material 304 are exposed for subsequent thermal oxidation.

Then, referring to FIG. 3G, a thermal oxidation method is performed to form a gate dielectric layer 210 on the sidewalls in the first trench 202a and the second trench 202b, and simultaneously form an inter-gate dielectric layer 212 on the first gate 204. Moreover, the inter-gate dielectric layer 212 on the first gate 204 is thicker than the gate dielectric layer 210 in the first trench 202a. That is, in FIG. 3G, it is shown that the gate dielectric layer 210 is mostly formed on the sidewalls of the first trench 202a and the second trench 202b, and the inter-gate dielectric layer 212 is located on the first gate 204. Specifically, in the present embodiment, the exposed portion of the first gate 204 is oxidized into the inter-gate dielectric layer 212, and the conductive material 304 located in the second trench 202b is subjected to thermal oxidation to be completely oxidized into the inter-gate dielectric layer 212.

Moreover, in the present embodiment, the method of forming the inter-gate dielectric layer 212 in the second trench 202b includes completely and thermally oxidizing the conductive material 304 in the second trench 202b. In another embodiment, the method of forming the inter-gate dielectric layer 212 in the second trench 202b includes partially and thermally oxidizing the conductive material 304 in the second trench 202b, and an extending portion for forming the first gate 204 is extended from the first trench 202a into the second trench 202b, and the extending portion may be located between the epitaxial layer 202 and the inter-gate dielectric layer 212. Specifically, the extending portion is a part of the first gate 204, and therefore the material thereof is the same as the first gate 204, for example, polysilicon. In the embodiment, the extending portion has the same potential as the first gate 204.

Next, referring to FIG. 3H, a second gate 206 is formed in the first trench 202a and the second trench 202b, and the second gate 206 is located on the inter-gate dielectric layer 214. Specifically, the second gate 206 is, for example, a conductive layer formed in the first trench 202a and the second trench 202b by using the chemical vapor deposition, the physical vapor deposition or other suitable film forming process, and the conductive layer is formed by being subjected to a chemical mechanical polishing process or etching, wherein the conductive layer is, for example, polysilicon. In addition, in the embodiment, the material of the first gate 204 may be the same as the material of the second gate 206; that is, the material of the first gate 204 and the second gate 206 is, for example, polysilicon. In this embodiment, the first gate 204 may serve as a shielded gate, and the second gate 206 may serve as a control gate for controlling the on/off of the split-gate MOSFET.

After forming the gate structure, referring to FIG. 3I, a well region 306 may be formed in the epitaxial layer 202 by using an ion implantation process or the like, and a source region 308 may be formed on the surface of the epitaxial layer 202. In the present embodiment, the substrate 200 is, for example, an N+ type doped substrate, which may serve as a drain region of the split-gate MOSFET; the well region 306 is, for example, a P-type well; the source region 308 is, for example, an N+doped region. In another embodiment, the well region 306 and the source region 308 may be formed first in the epitaxial layer 202 before the first trench 202a and the second trench 202b are formed.

In the embodiment, since the width W3 of the first trench 202a is larger than the width W4 of the second trench 202b, and the ratio (W4/W3) of the widths is controlled to effectively exhibit micro-loading effect of etch rate, when the density of the second gate 216 (control gate) is increased, it is possible to use only one photomask to complete trenches with different depths simultaneously. Therefore, the disclosure can be integrated into the existing process to effectively increase the device channel density and reduce the channel resistance.

In summary, the disclosure can form the first trench and the second trench of different widths and depths simultaneously by using one photomask, and can effectively increase the density of the second gate and reduce the channel resistance when the device is turned on without greatly changing the existing process.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A gate structure of a split-gate metal oxide semiconductor field effect transistor (MOSFET), comprising:
a substrate;
an epitaxial layer, formed on the substrate, and the epitaxial layer having a first trench and a second trench with different extending directions, wherein the first trench and the second trench have an overlapping region, a width of the first trench is greater than a width of the second trench, and a depth of the first trench is greater than a depth of the second trench;
a first gate, located in the first trench;
a second gate, located in the second trench and the first trench on the first gate;
a bottom dielectric layer, located between the first gate and the epitaxial layer;
a gate dielectric layer, located between the second gate and the epitaxial layer; and
an inter-gate dielectric layer, located between the first gate and the second gate.

2. The gate structure of the split-gate MOSFET according to claim 1, wherein a ratio of the width of the second trench and the width of the first trench is to effectively exhibit micro-loading effect of etch rate.

3. The gate structure of the split-gate MOSFET according to claim 1, wherein a ratio of the depth of the second trench and the depth of the first trench is 0.8 or less.

4. The gate structure of the split-gate MOSFET according to claim 1, wherein the first gate further comprises an extending portion extending from the first trench into the second trench.

5. The gate structure of the split-gate MOSFET according to claim 4, wherein the inter-gate dielectric layer is further disposed between the extending portion and the second gate.

6. The gate structure of the split-gate MOSFET according to claim 1, wherein the first trench and the second trench are arranged in a cross shape or a gird shape.

7. The gate structure of the split-gate MOSFET according to claim 1, wherein the first trench and the second trench are arranged in T-shape.

8. The gate structure of the split-gate MOSFET according to claim 1, wherein a material of the first gate and the second gate comprises polysilicon.

9. The gate structure of the split-gate MOSFET according to claim 1, wherein the epitaxial layer comprises an N-type doped epitaxial layer or a P-type doped epitaxial layer.

10. A manufacturing method of a gate structure of a split-gate MOSFET, comprising:
forming an epitaxial layer on a substrate;
forming a patterned photomask on the epitaxial layer, the patterned photomask having a first opening and a second opening with different extending directions, wherein the first opening and the second opening have an overlapping region, and a width of the first opening is greater than a width of the second opening;
etching the epitaxial layer with the patterned photomask as a mask to form a first trench and a second trench in the epitaxial layer, wherein the first trench and the second trench have an overlapping region, a width of the first trench is greater than a width of the second trench, and a depth of the first trench is greater than a depth of the second trench;
forming a bottom dielectric layer on surfaces of the first trench and the second trench;
forming a conductive material in the first trench and the second trench;
etching back the conductive material to form a first gate and expose a portion of the bottom dielectric layer;
removing the exposed bottom dielectric layer;
performing a thermal oxidation method to form a gate dielectric layer on sidewalls in the first trench and the second trench and to form an inter-gate dielectric layer on the first gate simultaneously; and
forming a second gate in the first trench and the second trench.

11. The manufacturing method of the gate structure of the split-gate MOSFET according to claim 10, wherein the method of forming the bottom dielectric layer comprises a deposition method or a thermal oxidation method.

12. The manufacturing method of the gate structure of the split-gate MOSFET according to claim 10, wherein a ratio of the width of the second opening to the width of the first opening is to effectively exhibit micro-loading effect of etch rate.

13. The manufacturing method of the gate structure of the split-gate MOSFET according to claim 10, wherein a ratio of the depth of the second trench to the depth of the first trench is 0.8 or less.

14. The manufacturing method of the gate structure of the split-gate MOSFET according to claim 10, wherein the method of forming the inter-gate dielectric layer comprises completely and thermally oxidizing the conductive material in the second trench.

15. The manufacturing method of the gate structure of the split-gate MOSFET according to claim 10, wherein the method of forming the inter-gate dielectric layer comprises partially and thermally oxidizing the conductive material in the second trench to form an extending portion of the first gate extending from the first trench into the second trench.

16. The manufacturing method of the gate structure of the split-gate MOSFET according to claim 10, wherein a material of the first gate and the second gate comprises polysilicon.

17. The manufacturing method of the gate structure of the split-gate MOSFET according to claim 10, wherein the epitaxial layer comprises an N-type doped epitaxial layer or a P-type doped epitaxial layer.
